(19) United States
(12) Patent Application Publication
(10) Pub. No.: US 2003/0116784 A1
(43) Pub. Date: Jun. 26, 2003

(54) DRAM array bit contact with relaxed pitch pattern

(75) Inventors: Rama Divakaruni, Ossining, NY (US); Carl J. Radens, LaGrangeville, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY

(21) Appl. No.: 10/026,119

(22) Filed: Dec. 21, 2001

(51) Int. Cl. H01L 31/0328

(52) U.S. Cl. 257/200

(57) ABSTRACT

The invention provides improved DRAM cells using dual gate transistors, DRAM arrays and devices using DRAM cells as well as improved methods for manufacturing such cells, arrays and devices. The DRAM cells of the invention are characterized by the use of a shared bitline contact for each dual gate transistor. The DRAM arrays and devices of the invention are characterized by use of the DRAM cells of the invention and preferably by the use of a relaxed pitch layout for the bitline contacts. The techniques for manufacturing the DRAM arrays and devices of the invention are preferably characterized by use of a relaxed pitch bitline contact configuration which avoids the need for a critical mask.

### BACKGROUND OF THE INVENTION

The microelectronics industry has been driven by the desire for increased device density. One component of most microelectronics systems where this desire is most evident is dynamic random access memory (typically, as a separate chip connected to a logic chip and/or as an a macro embedded on a logic chip).

Recent trends in advanced DRAM memory cell design have employed so-called vertical transistors. See for example, U.S. Pat. Nos. 6,150,670; 6,177,698; 6,184,091; 6,200,851, 6,281,539; and 6,288,422, the disclosures of which are incorporated herein by reference.

In memory cell designs using vertical transistors, it is often desired to use a dual gate configuration where a common gate conductor controls two source/drain combinations on opposite sides of the trench which contains the gate conductor. Such configurations provide improved cell scalability regarding most electrical properties. Unfortunately, it is problematic to form the multiple bitline contacts required by such processes especially as ground rule is reduced. In some instances, such bitline contacts can be formed using a critical mask, however, such approaches add significantly to manufacturing cost and complexity.

Thus, there is a need for improved DRAM cells using dual gate transistors, DRAM arrays and devices using DRAM cells as well as improved manufacturing techniques therefor.

### SUMMARY OF THE INVENTION

The invention provides improved DRAM cells using dual gate transistors, DRAM arrays and devices using DRAM cells as well as improved methods for manufacturing such cells, arrays and devices. The DRAM cells of the invention are characterized by the use of a shared bitline contact for each dual gate transistor. The DRAM arrays and devices of the invention are characterized by use of the DRAM cells of the invention and preferably by the use of a relaxed pitch layout for the bitline contacts. The techniques for manufacturing the DRAM arrays and devices of the invention are preferably characterized by use of a relaxed pitch bitline contact configuration which avoids the need for a critical mask.

In one aspect, the invention encompasses a DRAM cell array in a semiconductor substrate, the array comprising DRAM cells, each cell including:

(i) a storage capacitor,

(ii) dual gate transistor connected to the storage capacitor, and

(iii) a bitline contact shared by the dual gates of the transistor.

The bitline contacts and the array cells are preferably arranged in substantially parallel rows such that each row of bitline contacts is separated in distance by at least two rows of array cells. The dual gate transistors are preferably vertical transistors and the storage capacitors are preferably trench capacitors. The DRAM cell array may form part of an embedded DRAM device and/or part of a stand alone DRAM device.

In another aspect, the invention encompasses a method of forming a DRAM cell array in a semiconductor substrate, the array comprising rows of DRAM cells, each cell including:

(i) a storage capacitor,

(ii) a respective dual gate transistor connected to each storage capacitor, and

(iii) a bitline contact shared by the dual gates of the transistor,

The Method Comprising:

(a) providing a substrate having an array of cells, each comprising

(i) a storage capacitor, and

(ii) a respective dual gate transistor connected to each storage capacitor,

(b) providing gate contacts at each transistor and wordlines connecting the gate contacts, the gate contacts and wordlines having a dielectric cap and dielectric sidewall spacer,

(c) providing further dielectric material to fill spaces between the wordlines,

(d) planarizing the further dielectric material to stop at the caps,

(e) depositing an etch stop layer over the planarized dielectric material and caps,

(f) providing a stripe-patterned mask over the etch stop layer, the mask having stripe spaces where the etch stop layer is exposed, the stripe spaces being substantially parallel to the wordlines, the stripe spaces being over the spaces between the wordlines,

(g) removing the etch stop at the stripe spaces,

(h) depositing an interlevel dielectric layer,

(i) providing a bitline stripe-patterned mask over the interlevel dielectric layer, the mask having bitline stripe spaces where the interlevel dielectric layer is exposed, the bitline stripe spaces corresponding to locations for bitline contacts at the transistors and bitlines connecting the bitline contacts,

(j) removing dielectric material at the bitline stripe spaces to provide damascene trenches for the bitline contacts and bitlines, and

(k) filling the damascene trenches with metallization to form the bitline contacts and bitlines.

In an alternative aspect, the invention encompasses a method of forming a DRAM cell array in a semiconductor substrate, the array comprising rows of DRAM cells, each cell including:

(i) a storage capacitor,

(ii) a respective dual gate transistor connected to each storage capacitor, and

(iii) a bitline contact shared by the dual gates of the transistor,

The Method Comprising:

(a) providing a substrate having an array of cells, each comprising

(i) a storage capacitor, and

(ii) a respective dual gate transistor connected to each storage capacitor,

(b) providing gate contacts at each transistor and wordlines connecting the gate contacts, the gate contacts and wordlines having a dielectric cap and dielectric sidewall spacer,

(c) providing further dielectric material to fill spaces between the wordlines,

(d) planarizing the further dielectric material to stop at the caps,

(e) depositing an etch stop layer over the planarized dielectric material and caps,

(f) depositing an interlevel dielectric layer over the etch stop layer,

(g) providing a bitline contact patterned mask over the interlevel dielectric layer, the mask having rows of bitline contact spaces where the interlevel dielectric layer is exposed, the rows of bitline contact spaces, the rows of bitline contact spaces being positioned near the transistors to define bitline contact locations,

(h) removing the interlevel dielectric and the etch stop at the bitline contact spaces,

(i) providing a bitline stripe-patterned mask over the interlevel dielectric layer, the mask having bitline stripe spaces where the interlevel dielectric layer is exposed, the bitline stripe spaces corresponding to locations for bitline contacts at the transistors and bitlines connecting the bitline contacts,

(j) removing dielectric material at the bitline stripe spaces to provide damascene trenches for the bitline contacts and bitlines, and

(k) filling the damascene trenches with metallization to form the bitline contacts and bitlines.

In the methods of the invention, the bitline contacts are preferably formed in rows spaced by at least twice the minimum lithographic dimension of the chip.

These and other aspects of the invention are described in further detail below.

### BRIEF DESCRIPTION OF THE DRAWINGS

FIG. 1 shows a schematic plan view of a cell layout for a portion of a DRAM cell array according to the invention with trench capacitor pattern, wordlines, active areas and bitlines.

FIG. 2 shows a schematic plan view of bitline contact mask open area useful for forming the a cell layout of FIG. 1.

FIG. 3 shows a schematic cross section view at line B-B of FIG. 2 of a patterned wordline conductor, gate cap, dielectric spacer, and dielectric fill after planarization, prior to formation of the CB open mask. The underlying capacitor and transistor components are omitted.

FIG. 4 shows the schematic cross section of FIG. 3 with formation of an etch stop layer.

FIG. 5 shows the schematic cross section of FIG. 4 with the CB open mask after patterning of the etch stop layer.

FIG. 6 shows the schematic cross section of FIG. 5 with the M0 interlevel dielectric layer over the patterned etch stop layer according to an embodiment of the invention.

FIG. 7 shows the schematic cross section of FIG. 6 M0/CB after removal of interlevel dielectric to form spaces for bitlines and removal of dielectric from between the gate stacks for the bitline contacts.

FIG. 8 shows a second embodiment of the invention where dielectric is removed from between the gate stacks after patterning of the etch stop shown in FIG. 5.

FIG. 9 shows the schematic cross section of FIG. 8 after interlevel dielectric deposition.

FIG. 10 shows the schematic cross section of FIG. 9 where interlevel dielectric has been removed for bitlines and bitline contacts to form a dual damascene structure.

FIG. 11a shows a third embodiment of the invention where interlevel dielectric is deposited after formation of an etch stop layer shown in FIG. 4.

FIG. 11b shows the schematic cross section of FIG. 11 a after bitline contact pattering using lithography and selective etching stopping on the etch stop layer.

FIG. 11c shows the schematic cross section of FIG. 11b after the etch stop is layer patterned by etching.

FIG. 12 shows a schematic cross section (e.g., such as FIGS. 7, 10, or 11c) after the bit contact plug (polysilicon) formation and damascene bitline metallization formation, as well as showing the underlying capacitor, dual gate transistor, wordline and bitline.

### DETAILED DESCRIPTION OF THE INVENTION

The DRAM cells and cell arrays of the invention are characterized by the use of a shared bitline contact for each dual gate transistor. The DRAM arrays and devices of the invention are preferably further characterized by the use of a relaxed pitch layout for the bitline contacts. The techniques for manufacturing the DRAM arrays and devices of the invention are also preferably characterized by use of a relaxed pitch bitline contact configuration which avoids the need for a critical mask.

In one aspect, the invention encompasses a DRAM cell array in a semiconductor substrate, the array comprising DRAM cells, each cell including:

(i) a storage capacitor,

(ii) dual gate transistor connected to the storage capacitor, and

(iii) a bitline contact shared by the dual gates of the transistor.

The DRAM arrays of the invention would typically contain wordlines and bitlines necessary for functioning of the array as a memory array. The DRAM devices of the invention would typically contain the array(s) of the invention together with any support circuitry needed for the array to function as an embedded DRAM device and/or as a stand-alone DRAM device.

The bitline contacts and the array cells are preferably arranged in substantially parallel rows such that each row of bitline contacts is separated in distance by at least two rows of array cells. Preferably, the spacing of the bitline contact rows is at least twice the minimum lithographic feature size (F). The bitline contacts and bitlines preferably form part of a dual damascene structure. The invention is not limited to any specific dual gate transistor or storage capacitor configuration. The dual gate transistors are preferably vertical transistors and the storage capacitors are preferably trench capacitors. The DRAM cell array may form part of an embedded DRAM device and/or part of a stand alone DRAM device. Alternatively, the bitline contact pattern may be arranged such that the bitline contacts are separated by a single row of array cells, or along a diagonal direction to the orientation of the wordlines.

Other aspects of the cells, arrays and devices of the invention are described with the discussion of the figures below.

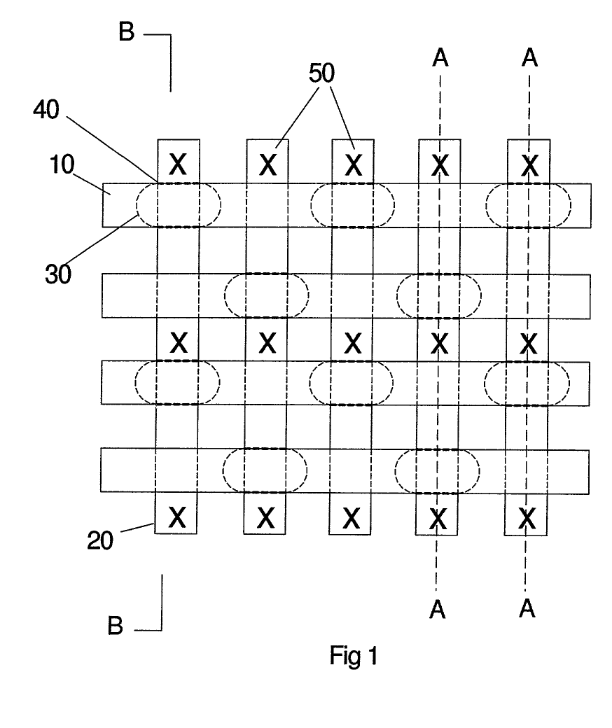

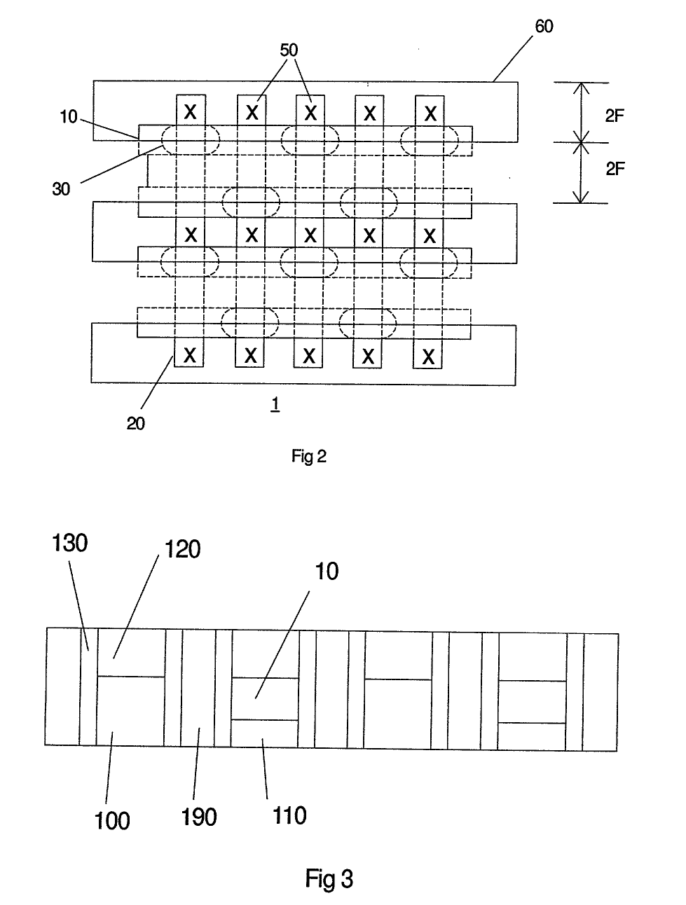

FIG. 1 shows a cell layout 1 having wordlines 10 and active areas 20. Also shown is a the location of the storage (trench) capacitors 30 under wordlines 10. The gate dielectric 40 of the dual gate transistors is also shown lying under the wordlines and active areas. The orientation where bitlines would be placed direction of bitlines is indicated by lines AA. While the invention is illustrated with parallel linear bitlines, the invention is open to other bitline configurations (e.g., folded or twisted bitlines, etc.). Location of the bitline contacts 50 is indicated the X's in FIG. 1. Referring to FIG. 2, the bitline contacts configuration enables use of a relaxed pitch CB pattern mask 60 spaced at 4F=2F+2F pitch.

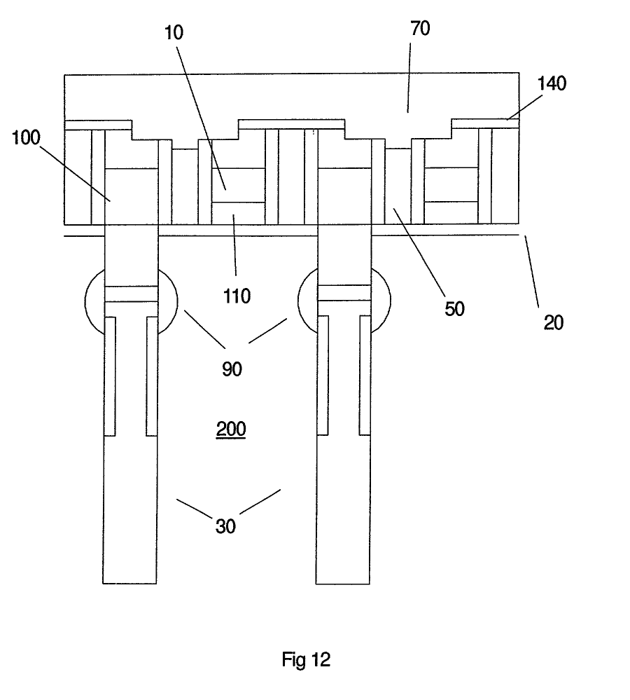

FIG. 12 shows a cross section taken at B-B of FIG. 1 after formation of the bitline contacts 50 and bitline(s) 70. The bitline contacts are preferably formed of polysilicon, however the invention is not limited to any specific contact composition. The bitlines may be formed from any desired conductive material such as tungsten, aluminum, copper, aluminum-copper alloys, suicides, etc. Also illustrated in FIG. 12 are the capacitor 30, dual gate transistor 80, dopant outdiffusions 90, gate contacts 100, wordlines 10, isolation 110, and active area 20. The conductors, isolation, dopants, and other materials forming the cells and devices of the invention may be selected from those known in the art. The invention is not limited to a specific materials set.

While the structures of the invention can be made by various methods, the invention also encompasses methods of forming a DRAM cell array in a semiconductor substrate, the array comprising rows of DRAM cells, each cell including:

(i) a storage capacitor,

(ii) a respective dual gate transistor connected to each storage capacitor, and

(iii) a bitline contact shared by the dual gates of the transistor,

The Method Comprising:

(a) providing a substrate having an array of cells, each comprising

(i) a storage capacitor, and

(ii) a respective dual gate transistor connected to each storage capacitor,

(b) providing gate contacts at each transistor and wordlines connecting the gate contacts, the gate contacts and wordlines having a dielectric cap and dielectric sidewall spacer,

(c) providing further dielectric material to fill spaces between the wordlines,

(d) planarizing the further dielectric material to stop at the caps,

(e) depositing an etch stop layer over the planarized dielectric material and caps,

(f) providing a stripe-patterned mask over the etch stop layer, the mask having stripe spaces where the etch stop layer is exposed, at least a portion of the stripe spaces being over the spaces between the wordlines,

(g) removing the etch stop at the stripe spaces,

(h) depositing an interlevel dielectric layer,

(i) providing a bitline stripe-patterned mask over the interlevel dielectric layer, the mask having bitline stripe spaces where the interlevel dielectric layer is exposed, the bitline stripe spaces corresponding to locations for bitline contacts at the transistors and bitlines connecting the bitline contacts,

(j) removing dielectric material at the bitline stripe spaces to provide damascene trenches for the bitline contacts and bitlines, and

(k) filling the damascene trenches with metallization to form the bitline contacts and bitlines.

The substrate provided in step (a) may be any semiconductor material, however, the substrate is preferably a silicon semiconductor such as those typically known in the art. Referring to FIG. 12, the storage capacitor 30 of the array cell is preferably a trench capacitor, and the dual gate transistor 80 is preferably a vertical channel transistor positioned above the storage capacitor 30 and connected to the storage capacitor 30 by outdiffusions 90. These components may be constructed by various methods known in the art.

In step (b), the gate contacts 100 and wordlines 10 may be provided by techniques known in the art such as those described in the above-referenced patents or by other techniques. A typical gate contact stack may include polysilicon, WSi, and W/WN. Referring to FIG. 3, except for the locations of the gate contacts 100, typically wordline 10 will be separated from the bulk substrate 200 by dielectric isolation material 110. The gate contacts 100 will typically be surrounded by a dielectric isolation material shown as cap 120 (preferably about 10-200 nm thick) and sidewalls 130 (preferably about 5-30 nm thick). The isolation surrounding the gate contact is preferably a nitride such as silicon nitride.

The dielectric fill provided in step (c) is preferably an oxide such as a boron phosphorus silicon oxide (BPSG) or other suitable filling and planarizing characteristics such as a spin-on-glass (SOG) material. The planarizing step (d) may be performed using any conventional planarization process. Preferably, step (d) is performed using chemical mechanical polishing (CMP). The planarized dielectric fill 140 is shown in FIG. 3.

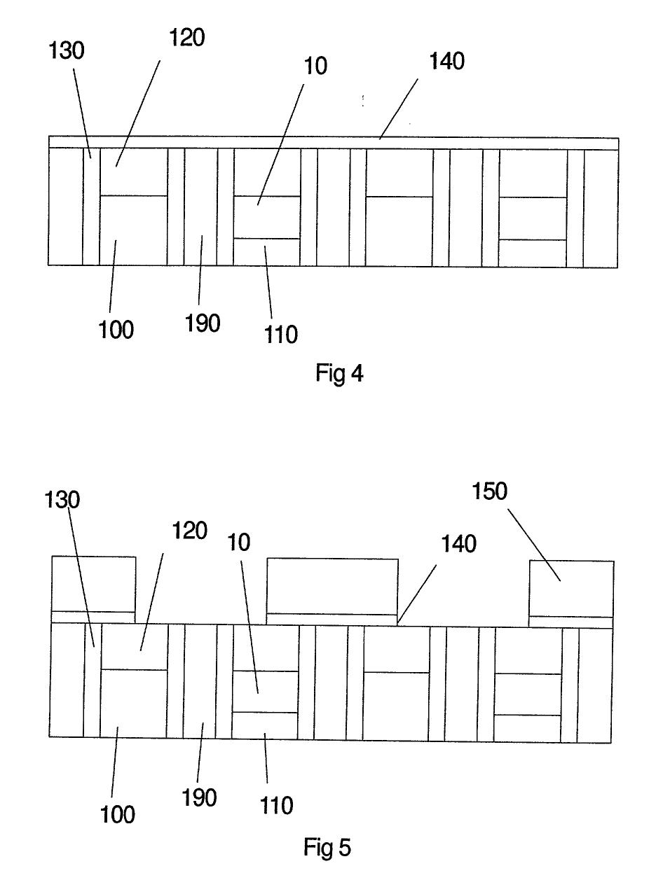

Referring to FIG. 4, the etch stop 140 is deposited in step (e), preferably by chemical vapor deposition or other technique for depositing a conformal layer. Preferably, the etch stop is a layer of about 5 nm-100 nm SiN or SiC. If desired, an additional layer (not shown) of about 5 nm-50 nm oxide such as TEOS or BPSG may be deposited before etch stop layer 140 is formed.

The etch stop layer is patterned in step (f) using a conventional photoresist mask 150 (in FIG. 5) in a stripe pattern which is preferably at the relaxed pitch illustrated in FIG. 2. Conventional photolithography and etching techniques (for step (f)) may be used to pattern etch stop layer 140 with the result as shown in FIG. 5.

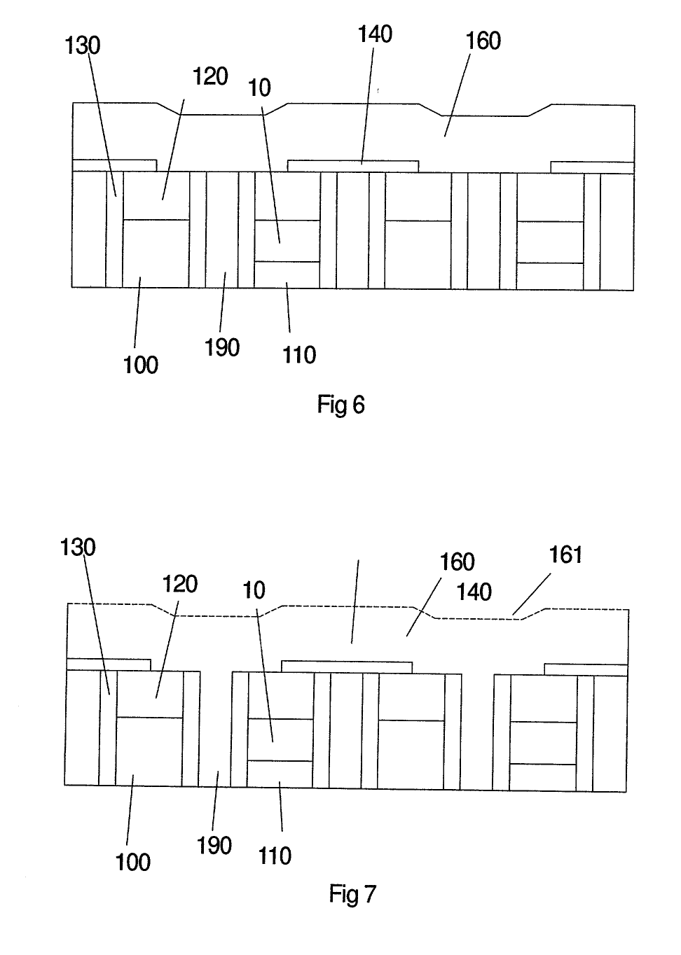

Portions of the photoresist mask not removed in the etching of the etch stop layer are preferably removed before step (g) by conventional techniques. The interlevel dielectric 160 in FIG. 6 is preferably deposited using chemical vapor deposition and/or spin-on techniques. The invention in not limited to any specific interlevel dielectric material, however inorganic oxides are generally preferred.

A further photoresist mask is provided over the interlevel dielectric to define the location of bitlines 70 in the interlevel dielectric layer 160. The mask is preferably a striped mask, however other configurations may be employed depending on the desired bitline configuration. The location of the bitlines is preferably such that the bitlines and bitline contacts act as a dual damascene structure. With the bitline mask in place, the spaces for the bitlines and bitline contacts are then preferably formed in step (j) by anisotropic etching of the interlevel dielectric and exposed dielectric 190 between the wordlines to give a structure as shown in FIG. 7 where the dotted line 161 indicates space etched in the interlevel dielectric for the bitline.

Where support regions for the array (i.e., areas where support circuitry is located) are formed simultaneously, the pattern in the support (not shown) will form a conventional damascene pattern. The etch stop pattern was cleared in the support by the CS contact patterning.

The resulting spaces for bitline contacts and bitlines can be filled with conductive material. The invention is not limited to any specific conductive materials or filling techniques.

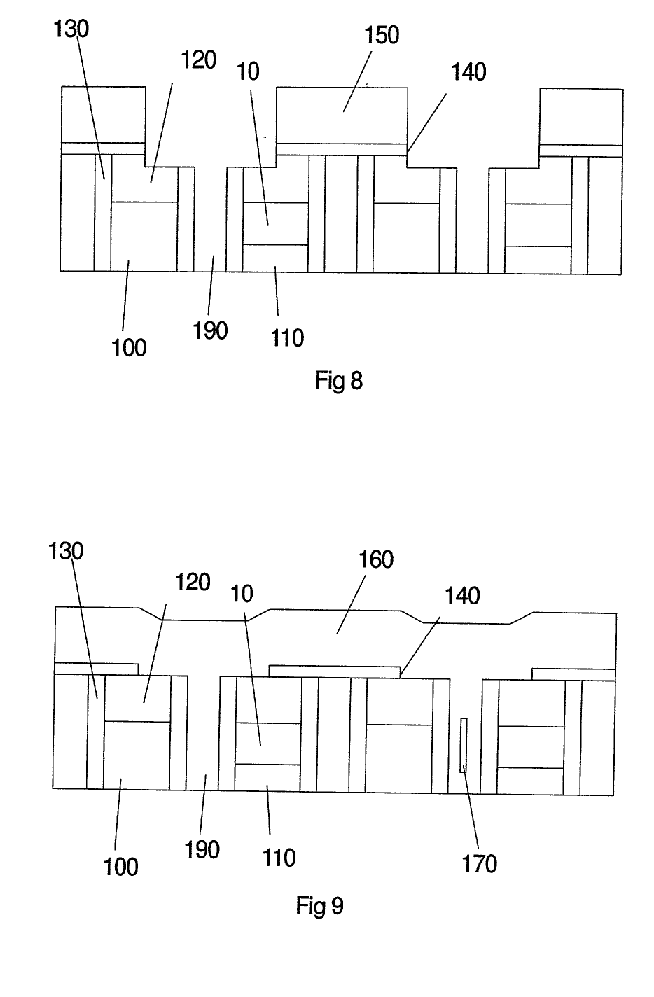

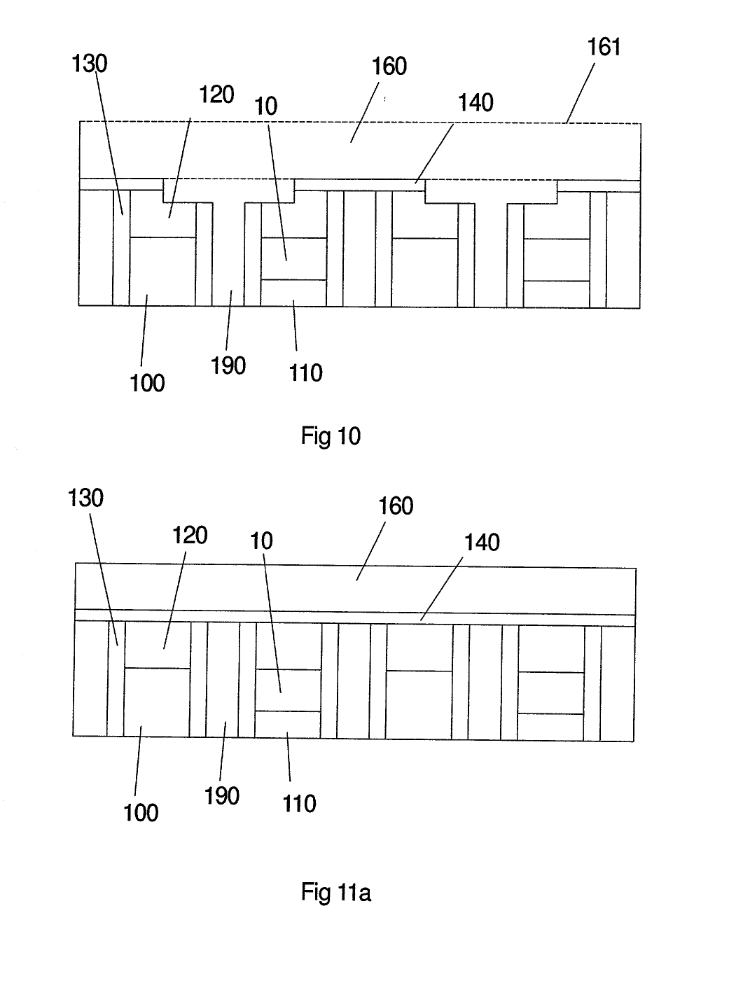

FIG. 8 shows a variation of above method of the invention where dielectric is removed from between the gate stacks after patterning of the etch stop shown in FIG. 5. After removal of mask 150, interlevel dielectric 160 is deposited as shown in FIG. 9. Where the interlevel dielectric fills the spaces between the wordlines, voids 170 may arise depending on the actual ground rule, filling technique, etc. The interlevel dielectric 160 would then be etched in step (j) as above to give the structure of FIG. 10 having spaces for the bitline and bitline contact materials provided in step (k).

The invention also includes alternative methods of forming a DRAM cell array in a semiconductor substrate, the array comprising rows of DRAM cells, each cell including:

(i) a storage capacitor,

(ii) a respective dual gate transistor connected to each storage capacitor, and

(iii) a bitline contact shared by the dual gates of the transistor,

The Method Comprising:

(a) providing a substrate having an array of cells, each comprising

(i) a storage capacitor, and

(ii) a respective dual gate transistor connected to each storage capacitor,

(b) providing gate contacts at each transistor and wordlines connecting the gate contacts, the gate contacts and wordlines having a dielectric cap and dielectric sidewall spacer,

(c) providing further dielectric material to fill spaces between the wordlines,

(d) planarizing the further dielectric material to stop at the caps,

(e) depositing an etch stop layer over the planarized dielectric material and caps,

(f) depositing an interlevel dielectric layer over the etch stop layer,

(g) providing a bitline contact patterned mask over the interlevel dielectric layer, the mask having rows of bitline contact spaces where the interlevel dielectric layer is exposed, the rows of bitline contact spaces, the rows of bitline contact spaces being positioned near the transistors to define bitline contact locations,

(h) removing the interlevel dielectric and the etch stop at the bitline contact spaces,

(i) providing a bitline stripe-patterned mask over the interlevel dielectric layer, the mask having bitline stripe spaces where the interlevel dielectric layer is exposed, the bitline stripe spaces corresponding to locations for bitline contacts at the transistors and bitlines connecting the bitline contacts,

(j) removing dielectric material at the bitline stripe spaces to provide damascene trenches for the bitline contacts and bitlines, and

(k) filling the damascene trenches with metallization to form the bitline contacts and bitlines.

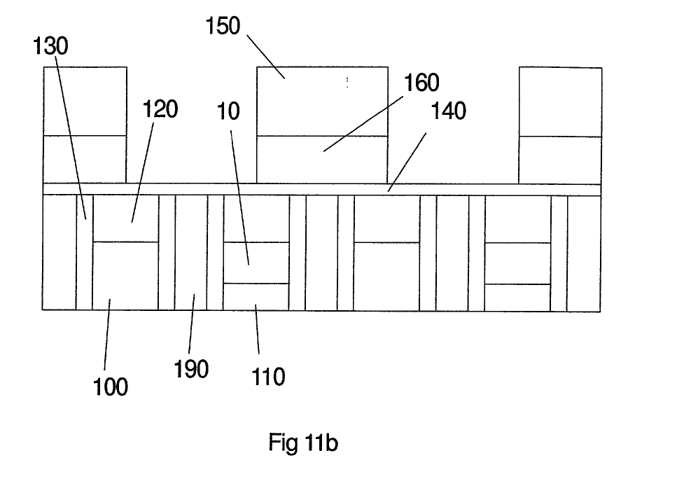

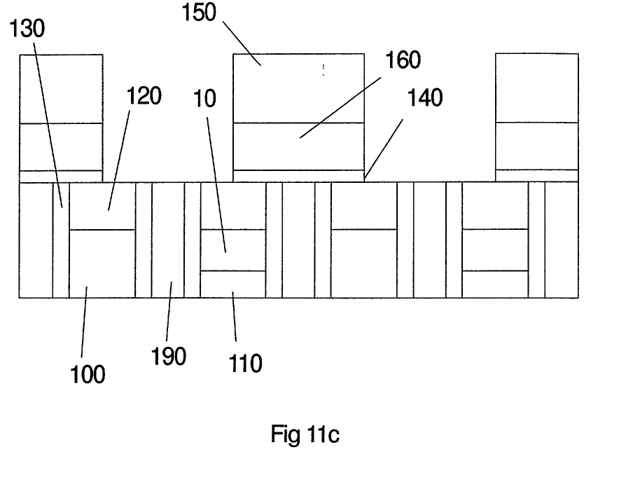

Referring to FIGS. 11a-11c, the primary differences in the alternative method are illustrated. As shown in FIG. 11 a, interlevel dielectric 160 is deposited directly over unpatterned etch stop 140. The photoresist mask 150 with the relaxed pitch pattern is then provided in step (g) to define the location of the bitline contacts with a selective etch process stopping on etch stop 140 as shown in FIG. 11b. The etch stop 140 is then patterned using a non-selective RIE as shown in FIG. 11c.

In the methods of the invention, the bitline contacts are preferably formed in rows spaced by at least twice the minimum lithographic dimension of the chip. The rows of bitline contact spaces are substantially parallel.

What is claimed is:

1. A DRAM cell array in a semiconductor substrate, said array comprising DRAM cells, each cell including:
(i) a storage capacitor,
(ii) dual gate transistor connected to said storage capacitor, and
(iii) a bitline contact shared by said dual gates of said transistor.

2. The DRAM cell array of claim 1 wherein said bitline contacts and said array cells are arranged in substantially parallel rows such that each row of bitline contacts is separated in distance by at least two rows of array cells.

3. The DRAM cell array of claim 1 wherein said dual gate transistor is a vertical transistor.

4. The DRAM cell array of claim 1 wherein said storage capacitor is a trench capacitor.

5. The DRAM cell array of claim 1 wherein said array forms part of an embedded DRAM device.

6. The DRAM cell array of claim 1 wherein said array forms part of a stand alone DRAM device.

7. The DRAM cell array of claim 2 further comprising bitlines running over and connected to said bitline contacts.

8. The DRAM cell array of claim 7 wherein said bitline contacts and said bitlines form part of a dual damascene structure.

9. The DRAM cell array of claim 7 further comprising wordlines connected to the gates of said transistors, said wordlines being substantially parallel to said rows of bitline contacts.

10. A method of forming a DRAM cell array in a semiconductor substrate, said array comprising rows of DRAM cells, each cell including:
(i) a storage capacitor,
(ii) a respective dual gate transistor connected to each storage capacitor, and
(iii) a bitline contact shared by said dual gates of said transistor
said method comprising:
(a) providing a substrate having an array of cells, each comprising
(i) a storage capacitor, and
(ii) a respective dual gate transistor connected to each storage capacitor,
(b) providing gate contacts at each transistor and wordlines connecting said gate contacts, said gate contacts and wordlines having a dielectric cap and dielectric sidewall spacer,
(c) providing further dielectric material to fill spaces between said wordlines,
(d) planarizing said further dielectric material to stop at said caps,
(e) depositing an etch stop layer over said planarized dielectric material and caps,
(f) providing a stripe-patterned mask over said etch stop layer, said mask having stripe spaces where said etch stop layer is exposed, at least a portion of said stripe spaces being over said spaces between said wordlines,
(g) removing said etch stop at said stripe spaces,
(h) depositing an interlevel dielectric layer,
(i) providing a bitline stripe-patterned mask over said interlevel dielectric layer, said mask having bitline stripe spaces where said interlevel dielectric layer is exposed, said bitline stripe spaces corresponding to locations for bitline contacts at said transistors and bitlines connecting said bitline contacts,
(j) removing dielectric material at said bitline stripe spaces to provide damascene trenches for said bitline contacts and bitlines, and
(k) filling said damascene trenches with metallization to form said bitline contacts and bitlines.

11. The method of claim 10 wherein said rows of bitline contact spaces are substantially parallel.

12. The method of claim 10 wherein said rows of bitline contact spaces are spaced apart by at least twice the minimum lithographic feature size.

13. The method of claim 10 wherein said etch stop layer is a silicon nitride.

14. The method of claim 10 wherein said interlevel dielectric is selected from the group consisting of inorganic oxides and organic resins.

15. The method of claim 10 wherein said removing of step (h) comprises reactive ion etching.

16. The method of claim 10 wherein said metallization of step (k) is planarized.

17. A method of forming a DRAM cell array in a semiconductor substrate, said array comprising rows of DRAM cells, each cell including:
(i) a storage capacitor,
(ii) a respective dual gate transistor connected to each storage capacitor, and
(iii) a bitline contact shared by said dual gates of said transistor
said method comprising:
(a) providing a substrate having an array of cells, each comprising
(i) a storage capacitor, and
(ii) a respective dual gate transistor connected to each storage capacitor,
(b) providing gate contacts at each transistor and wordlines connecting said gate contacts, said gate contacts and wordlines having a dielectric cap and dielectric sidewall spacer,
(c) providing further dielectric material to fill spaces between said wordlines,
(d) planarizing said further dielectric material to stop at said caps,
(e) depositing an etch stop layer over said planarized dielectric material and caps,
(f) depositing an interlevel dielectric layer over said etch stop layer,
(g) providing a bitline contact patterned mask over said interlevel dielectric layer, said mask having rows of bitline contact spaces where said interlevel dielectric layer is exposed, said rows of bitline contact spaces, said rows of bitline contact spaces being positioned near said transistors to define bitline contact locations,
(h) removing said interlevel dielectric and said etch stop at said bitline contact spaces,
(i) providing a bitline stripe-patterned mask over said interlevel dielectric layer, said mask having bitline stripe spaces where said interlevel dielectric layer is exposed, said bitline stripe spaces corresponding to locations for bitline contacts at said transistors and bitlines connecting said bitline contacts,
(j) removing dielectric material at said bitline stripe spaces to provide damascene trenches for said bitline contacts and bitlines, and
(k) filling said damascene trenches with metallization to form said bitline contacts and bitlines.

18. The method of claim 17 wherein said rows of bitline contact spaces are substantially parallel.

19. The method of claim 17 wherein said rows of bitline contact spaces are spaced apart by at least twice the minimum lithographic feature size.
